(19) United States
(12) Patent Application Publication
(10) Pub. No.: US 2012/0045892 A1
(43) Pub. Date: Feb. 23, 2012

(54) METHOD FOR FABRICATING SEMICONDUCTOR DEVICE

(75) Inventor: Naohisa SENGOKU, Osaka (JP)

(73) Assignees: IMEC, Leuven (BE); PANASONIC CORPORATION, Osaka (JP)

(21) Appl. No.: 13/278,709

(22) Filed: Oct. 21, 2011

Related U.S. Application Data
(63) Continuation of application No. PCT/JP2009/007345, filed on Dec. 28, 2009.

(30) Foreign Application Priority Data
Jun. 18, 2009 (JP) 2009-145467

(51) Int. Cl. H01L 21/28

(52) U.S. Cl. 438/592; 257/E21.19

(57) ABSTRACT

A gate insulating film is formed on a semiconductor substrate having a first region in which a first conductivity type transistor is formed and a second region in which a second conductivity type transistor is formed. Next, a metal film and a first metal nitride film are sequentially formed on the gate insulating film. Next, part of each of the metal film and the first metal nitride film that is located in the second region is removed, thereby exposing part of the gate insulating film that is located in the second region. Next, a second metal nitride film made of a same metal nitride as the first metal nitride film is formed on the part of the gate insulating film that is located in the second region.

### CROSS-REFERENCE TO RELATED APPLICATION

This is a continuation of PCT International Application PCT/JP2009/007345 filed on Dec. 28, 2009, which claims priority to Japanese Patent Application No. 2009-145467 filed on Jun. 18, 2009. The disclosures of these applications including the specifications, the drawings, and the claims are hereby incorporated by reference in their entirety.

### BACKGROUND

The present disclosure relates to a method for fabricating a semiconductor device which includes a transistor having a metal gate electrode, and specifically relates to improving properties of a transistor having a metal gate electrode.

To miniaturize devices and improve driving force of the devices, changing a gate structure from a conventional SiON/poly-Si gate electrode structure to a high-k/metal gate electrode structure has been considered. In the high-k/metal gate electrode structure, both of equivalent oxide thickness (EOT) and a gate leakage current can be reduced by using a high dielectric constant insulating film. Also, by using a metal film as a gate electrode, it is possible to prevent gate depletion in a poly-Si electrode. An objective of the high-k/metal gate electrode structure is to achieve desired work function suitable for each of an Nch field effect transistor (hereinafter referred to as “NFET”) and a Pch field effect transistor (hereinafter referred to as “PFET”).

FIGS. 4A-4G are cross-sectional views illustrating the steps of forming a transistor having a high-k/metal gate electrode structure according to the first conventional method (see Japanese Patent Publication No. 2007-110091).

In the first conventional method, as shown in FIG. 4A, a trench isolation 2 is formed in a semiconductor substrate 1 to partition the semiconductor substrate 1 into an NFET region and a PFET region. Then, a gate insulating film 3 made of such as a high dielectric constant insulator is formed on the semiconductor substrate 1. After that, a TiN film 5 having a thickness of about 20 nm is deposited on the gate insulating film 3.

Next, a mask pattern 6 is formed on the TiN film 5 to cover the PFET region as shown in FIG. 4B. After that, the TiN film 5 in the NFET region is removed by etching, and the mask pattern 6 is removed thereafter as shown in FIG. 4C.

Next, a TiN film 7 having a thickness of about 2.5 nm is deposited on the entire surface of the semiconductor substrate 1 as shown in FIG. 4D. After that, a silicon film 8 is deposited on the TiN film 7 as shown in FIG. 4E.

Next, by gate patterning, a gate electrode 9A made of the TiN film 5, the TiN film 7 and the silicon film 8 is formed in the PFET region, and a gate electrode 9B made of the TiN film 7 and the silicon film 8 is formed in the NFET region, as shown in FIG. 4F. Next, as shown in FIG. 4G, insulating sidewall spacers 10 are formed on the side surfaces of the gate electrodes 9A and 9B, and source/drain regions 11A and 11B are formed in the semiconductor substrate 1 on both lateral sides of each of the gate electrodes 9A and 9B.

As described above, in the first conventional method, the thick TiN film 5 and the thin TiN film 7 are used as a metal electrode in the PFET region, and the thin TiN film 7 is used as a metal electrode in the NFET region. Thus, a high work function is realized in the PFET region, and a low work function is realized in the NFET region.

FIGS. 5A-5F are cross-sectional views illustrating the steps of forming a transistor having a high-k/metal gate electrode structure according to the second conventional method (see Japanese Patent Publication No. 2001-203276).

In the second conventional method, as shown in FIG. 5A, a trench isolation 2 is formed in a semiconductor substrate 1 to partition the semiconductor substrate 1 into an NFET region and a PFET region. Then, a gate insulating film 3 made of a high dielectric constant insulator is formed on the semiconductor substrate 1. After that, a TiN film 5 is deposited on the gate insulating film 3.

Next, as shown in FIG. 5B, a mask pattern 6 is formed on the TiN film 5 to cover the PFET region, and then, nitrogen ions are implanted in the TiN film 5 in the NFET region with a dose amount of about 1×10¹⁴ cm⁻². After that, the mask pattern 6 is removed as shown in FIG. 5C. This nitrogen implantation modifies the TiN film 5 in the NFET region into a TiN film 5′ having a high nitrogen concentration.

Next, a tungsten film 13 is formed on the entire surface of the semiconductor substrate 1 as shown in FIG. 5D. Then, by gate patterning, a gate electrode 9A made of the TiN film 5 and the tungsten film 13 is formed in the PFET region, and a gate electrode 9B made of the TiN film 5′ and the tungsten film 13 is formed in the NFET region, as shown in FIG. 5E.

Next, as shown in FIG. 5F, insulating sidewall spacers 10 are formed on the side surfaces of the gate electrodes 9A and 9B, and source/drain regions 11A and 11B are formed in the semiconductor substrate 1 on both lateral sides of each of the gate electrodes 9A and 9B.

As described above, in the second conventional method, the gate electrode (i.e., a metal gate electrode) 9B in the NFET region has a higher work function than the gate electrode 9A in the PFET region due to the nitrogen implantation into the TiN film 5 in the NFET region.

### SUMMARY

However, it is impossible to achieve a desired work function suitable for each of the NFET and the PFET even if the first conventional method and the second conventional method are used.

Specifically, the work function required for the NFET is about 4.3 eV or less, and the work function required for the PFET is about 4.9 eV or more. However, even if the TiN film used for a gate electrode of the NFET is formed to have a thickness of about 2.5 nm, and the TiN film used for a gate electrode of the PFET is formed to have a thickness of about 20 nm in the first conventional method, the work function of the NFET and the work function of the PFET can only be about 4.4 eV and about 4.85 eV, respectively, which are not suitable work functions.

Further, even if an attempt is made to adjust the work functions by implanting nitrogen into the TiN film in the second conventional method, only the work function of the NFET can be reduced by about 0.1 eV, and it is impossible to achieve desired work functions of both of the NFET and the PFET at the same time.

In view of this, an objective of the present disclosure is to achieve work functions required for FETs of respective polarities in a high-k/metal gate electrode structure.

To achieve the above objective, a first method for fabricating a semiconductor device according to the present disclosure includes: a first step of forming a gate insulating film on a semiconductor substrate having a first region in which a first conductivity type transistor is formed and a second region in which a second conductivity type transistor is formed; a second step of sequentially forming a metal film and a first metal nitride film on the gate insulating film; a third step of removing part of each of the metal film and the first metal nitride film that is located in the second region, thereby exposing part of the gate insulating film that is located in the second region, and at a later time than the third step, a forth step of forming a second metal nitride film made of a same metal nitride as the first metal nitride film on the part of the gate insulating film that is located in the second region.

In the first method for fabricating the semiconductor device according to the present disclosure, the type of the gate insulating film formed in each of the transistor formation regions may differ between the transistor formation regions.

In the first method for fabricating the semiconductor device according to the present disclosure, the first metal nitride film may be made of a nitride of a metal which forms the metal film. Alternatively, a metal which forms the metal film may be a metal (e.g., Ta) which is different from the metal (e.g., Ti) contained in the first metal nitride film.

In the first method for fabricating the semiconductor device according to the present disclosure, in the fourth step, the second metal nitride film may also be formed on part of the gate insulating film that is located in the first region, and the method may further include: at a later time than the fourth step, a fifth step of patterning at least the second metal nitride film, the first metal nitride film and the metal film in the first region, thereby forming a first gate electrode; and at a later time than the fourth step, a sixth step of patterning at least the second metal nitride film in the second region, thereby forming a second gate electrode. In this case, the method may further include a seventh step of forming a conductive film on the second metal nitride film at a later time than the fourth step and prior to each of the fifth step and the sixth step, wherein in the fifth step, the first gate electrode is formed by patterning the conductive film, the second metal nitride film, the first metal nitride film and the metal film, and in the sixth step, the second gate electrode is formed by patterning the conductive film and the second metal nitride film. Further, in this case, the method may further include, at a later time than the seventh step, an eighth step of changing the metal film to a third metal nitride film by performing a heat treatment at a temperature of 800° C. or higher. Further, in this case, a nitrogen concentration of the third metal nitride film may be lower than a nitrogen concentration of the first metal nitride film, or the gate insulating film may include nitrogen, and a nitrogen concentration of the gate insulating film may be decreased in the eighth step. The heat treatment for changing the metal film to the third metal nitride film may be a heat treatment for impurity activation intended to form a source/drain region, for example. A lower portion of the metal film may remain as it is without being nitrided after the eighth step.

To achieve the above objective, a second method for fabricating a semiconductor device according to the present disclosure includes, a first step of forming a gate insulating film on a semiconductor substrate having a first region in which a first conductivity type transistor is formed and a second region in which a second conductivity type transistor is formed; a second step of forming a first metal nitride film on the gate insulating film; a third step of removing part of the first metal nitride film that is located in the second region, thereby exposing part of the gate insulating film that is located in the second region; and at a later time than the third step, a fourth step of forming a second metal nitride film made of a same metal nitride as the first metal nitride film on the part of the gate insulating film that is located in the second region, wherein the first metal nitride film has a nitrogen concentration and a thickness which are different from a nitrogen concentration and a thickness of the second metal nitride film.

In the second method for fabricating the semiconductor device according to the present disclosure, the type of the gate insulating film formed in each he transistor formation regions may differ between the transistor formation regions.

In the second method for fabricating the semiconductor device according to the present disclosure, in the fourth step, the second metal nitride film may also be formed on part of the gate insulating film that is located in the first region, and the method may further include: at a later time than the fourth step, a fifth step of patterning at least the second metal nitride film and the first metal nitride film in the first region, thereby forming a first gate electrode; and at a later time than the fourth step, a sixth step of patterning at least the second metal nitride film in the second region, thereby forming a second gate electrode. In this case, the method may further include a seventh step of forming a conductive film on the second metal nitride film at a later time than the fourth step and prior to each of the fifth step and the sixth step, wherein in the fifth step, the first gate electrode may be formed by patterning the conductive film, the second metal nitride film and the first metal nitride film, and in the sixth step, the second gate electrode may be formed by patterning the conductive film and the second metal nitride film.

In the first or second method for fabricating the semiconductor device according to the present disclosure, each of the first metal nitride film and the second metal nitride film may be made of TiN.

In the first or second method for fabricating the semiconductor device according to the present disclosure, a nitrogen concentration of the second metal nitride film may be higher than a nitrogen concentration of the first metal nitride film.

In the first or second method for fabricating the semiconductor device according to the present disclosure, the second metal nitride film may have a smaller thickness than the first metal nitride film.

In the first or second method for fabricating the semiconductor device according to the present disclosure, the gate insulating film may include a high dielectric constant insulating film. Here, the term “high dielectric constant insulating film” refers to an insulating film whose dielectric constant is higher than the dielectric constant of SiO₂.

In the first or second method for fabricating the semiconductor device according to the present disclosure, each of the first metal nitride film and the second metal nitride film may be formed by physical vapor deposition (PVD). In this case, each of the first metal nitride film and the second metal nitride film may be formed in a different ratio of a nitrogen gas flow rate to a total gas flow rate.

In the first or second method for fabricating the semiconductor device according to the present disclosure, the first conductivity type transistor may be a Pch transistor, and the second conductivity type transistor may be an Nch transistor. Alternatively, the first conductivity type transistor and the second conductivity type transistor may be of a same conductivity type.

A semiconductor device according to the present disclosure includes a first gate insulating film on a first region of a semiconductor substrate; and a first gate electrode on the first gate insulating film, wherein the first gate electrode at least includes a first metal nitride film and a second metal nitride film which is provided on the first metal nitride film and made of a same metal nitride as the first metal nitride film, and the first metal nitride film has a nitrogen concentration and a thickness which are different from a nitrogen concentration and a thickness of the second first metal nitride film.

In the semiconductor device according to the present disclosure, the first gate electrode may further include a conductive film on the second metal nitride film.

In the semiconductor device according to the present disclosure, the first gate electrode may further include a third metal nitride film formed under the first metal nitride film and having a nitrogen concentration lower than first metal nitride film. In this case, the first gate electrode may further include a metal film formed under the third metal nitride film.

In the semiconductor device according to the present disclosure, each of the first metal nitride film and the second metal nitride film may be made of TiN.

In the semiconductor device according to the present disclosure, a nitrogen concentration of the second metal nitride film may be higher than a nitrogen concentration of the first metal nitride film.

In the semiconductor device according to the present disclosure, the second metal nitride film may have a smaller thickness than the first metal nitride film.

The semiconductor device according to the present disclosure may further include a second gate insulating film on a second region of the semiconductor substrate; and a second gate electrode on the second gate insulating film, wherein the second gate electrode may include at least the second metal nitride film. In this case, the second gate insulating film may be the same insulating film as the first gate insulating film.

In the present disclosure, the first metal nitride film is formed on each of the first region in which the first conductivity type transistor is formed and the second region in which the second conductivity type transistor is formed. Then, part of the first metal nitride film that is located in the second region is removed. After that, the second metal nitride film made of the same metal nitride as the first metal nitride film is formed on the second region. Consequently, it is possible to form a metal electrode having a large thickness and a low nitrogen concentration (i.e., a gate electrode having a high work function) in the first region, and possible to form a metal electrode having a small thickness and a high nitrogen concentration (i.e., a gate electrode having a low work function) in the second region. Accordingly, work function values required for FETs of respective polarities can be obtained in a high-k/metal gate electrode structure.

Thus, the present disclosure relates to a semiconductor device and a method for fabricating the semiconductor device, and is particularly useful in improving properties of a transistor device having a metal gate electrode.

### BRIEF DESCRIPTION OF THE DRAWINGS

FIGS. 1A-1H are cross-sectional views for illustrating the steps of fabricating a semiconductor device according to the first embodiment of the present disclosure.

FIGS. 2A-2H are cross-sectional views for illustrating the steps of fabricating a semiconductor device according to the second embodiment of the present disclosure.

FIG. 3 is a diagram showing the correlation between a thickness of a TiN film in a gate electrode and a work function.

FIGS. 4A-4G are cross-sectional views for illustrating the steps of forming a transistor according to the first conventional method.

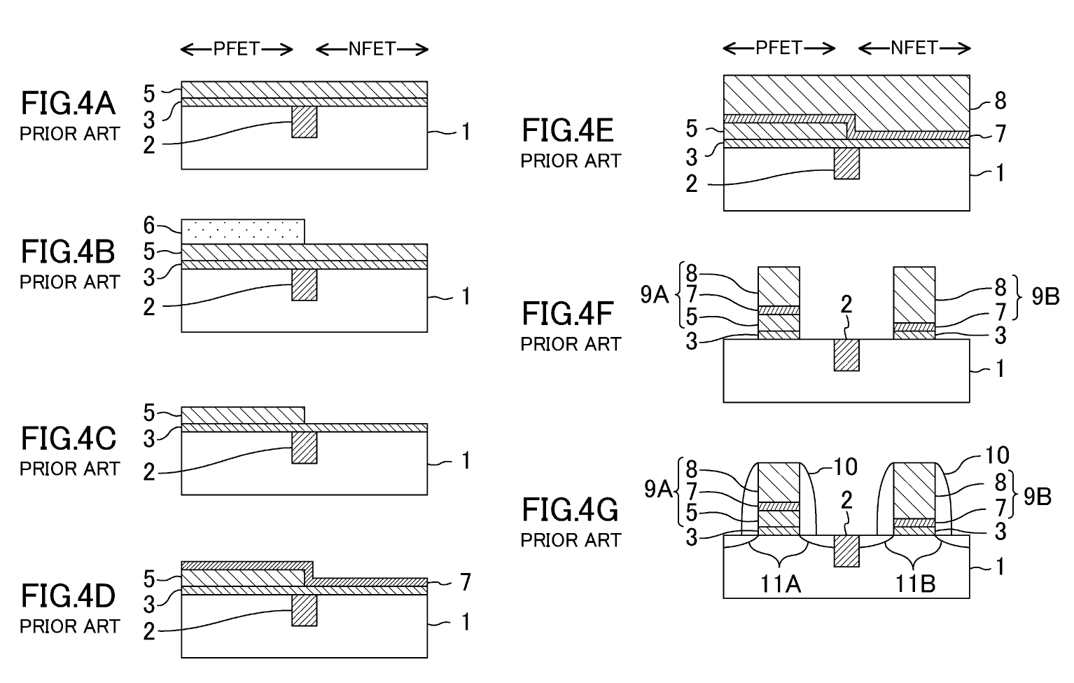

FIGS. 5A-5F are cross-sectional views for illustrating the steps of forming a transistor according to the second conventional method.

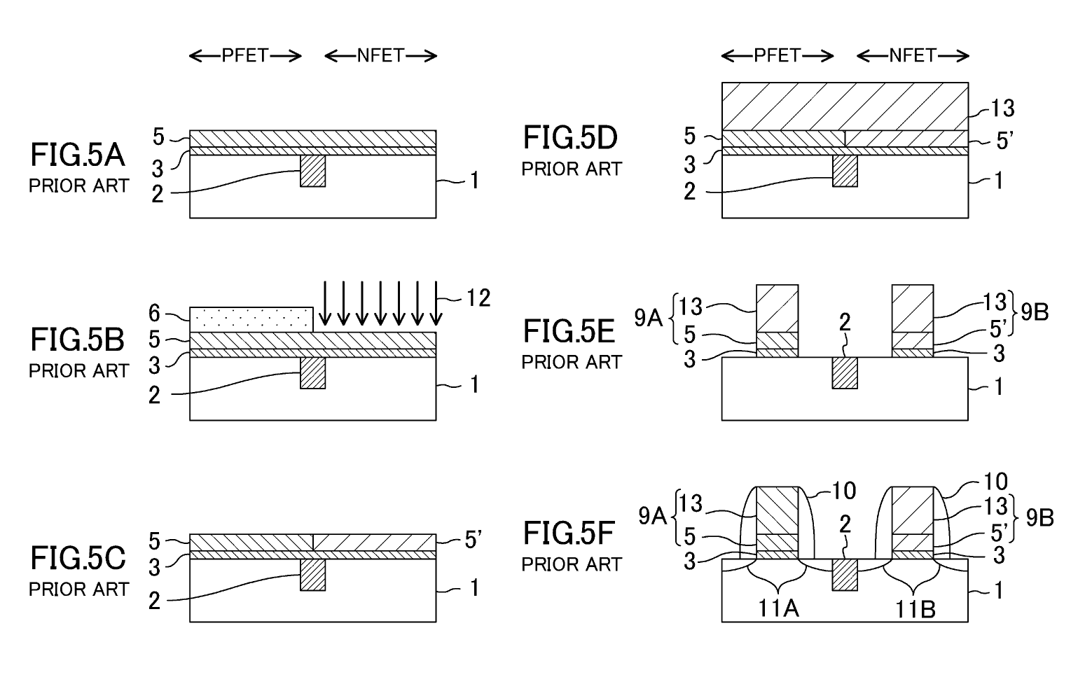

### DETAILED DESCRIPTION

### First Embodiment

A semiconductor device and a fabrication method thereof according to the first embodiment of the present disclosure will be described below with reference to the drawings.

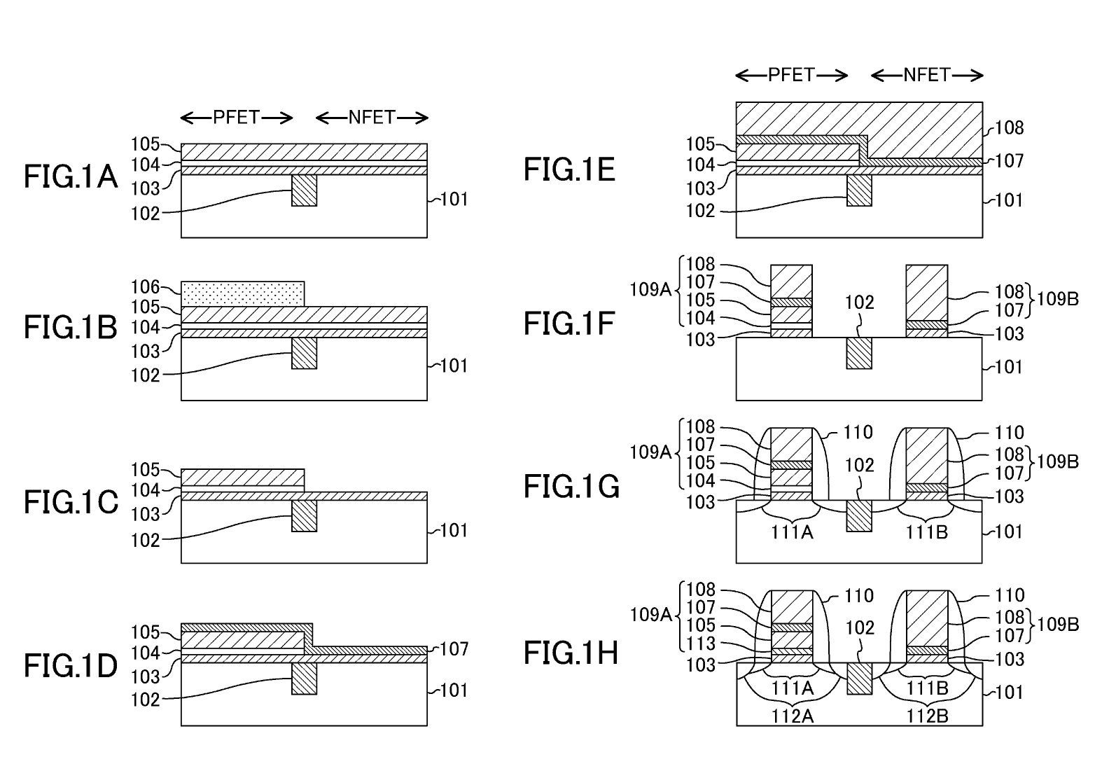

FIGS. 1A-1H are cross-sectional views for illustrating the steps of fabricating the semiconductor device according to the first embodiment.

First, as shown in FIG. 1A, an isolation structure 102 such as a shallow trench isolation (STI) structure is formed in a semiconductor substrate 101 to partition the semiconductor substrate 101 into an NFET region and a PFET region. Then, impurity implantation and activation are performed on the semiconductor substrate 101 in each FET region to adjust a threshold voltage (Vt). After that, an oxide film (not shown) on the surface of the semiconductor substrate 101 is removed. Subsequently, a thermal oxidation film having a thickness, for example, of about 1.5 nm, and a HfSiO film having a thickness, for example, of about 2.0 nm are sequentially deposited on the semiconductor substrate 101. The HfSiO film is nitrided to form a high dielectric constant gate insulating film 103 having a HfSiON/SiO₂ structure.

Next, as shown in FIG. 1A, a Ti film 104 having a thickness of about 2 nm is deposited on the high dielectric constant gate insulating film 103 by PVD, for example, and then, a TiN film 105 having a thickness of about 20 nm is deposited on the Ti film 104 by PVD, for example.

In the present embodiment, the thickness of the Ti film 104 is selected from a value range, for example, of about 1 nm to 3 nm. It is preferable to select the thickness of the TiN film 105 from a range of relatively large values, e.g., a value range of about 10 nm to 30 nm, to achieve a high work function. Further, it is preferable to set a nitrogen flow ratio (e.g., (N₂ flow rate)/(Ar flow rate+N₂ flow rate)) at the deposition of the TiN film 105 by PVD to a relatively low percentage, e.g., 40% or so, to reduce the nitrogen concentration (specifically, a composition ratio (a molar ratio)) of the TiN film 105 as much as possible, and achieve a high work function. If the nitrogen flow ratio is set to a low percentage, i.e., 40% or less, attention has to be paid because not a TiN film, but a Ti film may sometimes be deposited.

Next, a mask pattern 106 having an opening at the NFET region is formed on the TiN film 105 as shown in FIG. 1B. Then, part of the TiN film 105 and part of the Ti film 104 which are located in the NFET region are removed by, for example, wet etching, and the mask pattern 106 is removed thereafter, as shown in FIG. 1C. Consequently, part of the high dielectric constant gate insulating film 103 that is located in the NFET region is exposed. Here, examples of a wet etchant include an etchant by which an etch selectivity of the TiN film 105 to the high dielectric constant gate insulating film 103 becomes relatively high, and by which the TiN film 105 is etched at a relatively low etch rate (i.e., an etchant by which etching can be easily controlled), such as a dilute sulfuric acid-hydrogen peroxide mixture solution (a dilute SPM solution).

Next, as shown in FIG. 1D, a TiN film 107 having a thickness of about 2 nm is deposited on the entire surface of the semiconductor substrate 101, including part of an upper surface of the high dielectric constant gate insulating film 103 that is located in the NFET region (i.e., the portion where the high dielectric constant gate insulating film 103 is exposed) by, for example, setting a nitrogen flow ratio (e.g., (N₂ flow rate)/(Ar flow rate+N₂ flow rate)) to about 80% in PVD.

In the present embodiment, it is preferable to select the thickness of the TiN film 107 from a range of relatively small values, e.g., a value range of about 1 nm to 5 nm, to achieve a low work function. Further, it is preferable to select a nitrogen flow ratio at the deposition of the TiN film 107 by PVD from a range of relatively large values, e.g., a value range of about 80% to 100%, to increase the nitrogen concentration of the TiN film 107 as much as possible, and achieve a low work function.

Next, a polysilicon film 108 having a thickness, for example, of about 100 nm is deposited on the TiN film 107 as shown in FIG. 1E. Then, by gate patterning, a gate electrode 109A made of the Ti film 104, the TiN film 105, the TiN film 107 and the polysilicon film 108 is formed in the PFET region, and a gate electrode 109B made of the TiN film 107 and the polysilicon film 108 is formed in the NFET region, as shown in FIG. 1F. Here, part of the high dielectric constant gate insulating film 103 that is located outside the gate electrodes 109A and 109B is removed.

Next, impurities are implanted in the semiconductor substrate 101 using the gate electrodes 109A and 109B as masks to form a lightly doped drain (LDD) region 111A in the PFET region, and an LDD region 111B in the NFET region, as shown in FIG. 1G. After that, insulating sidewall spacers 110 are formed on the side surfaces of the gate electrodes 109A and 109B.

Next, impurities are implanted in the semiconductor substrate 101 using the gate electrodes 109A and 109B and the insulating sidewall spacers 110 as masks to form a source/drain region 112A in the PFET region, and a source/drain region 112B in the NFET region, as shown in FIG. 1H. Then, a heat treatment for activating the impurities in the source/drain regions 112A and 112B is performed, and thereafter, a silicide layer (not shown) containing, for example, Ni is formed in upper portions of the gate electrodes 109A and 109B and upper portions of the source/drain regions 112A and 112B to obtain a transistor structure.

In the present embodiment, the ultra thin Ti film 104 included in the gate electrode 109A in the PFET region is modified into a TiN film 113 (see FIG. 1H) during a process after the formation of the Ti film 104, e.g., during the above-mentioned heat treatment for impurity activation at a temperature of about 800° C. or more, by taking the nitrogen from the TiN film 105 on the Ti film 104. Here, a lower portion of the Ti film 104 may remain as it is without being nitrided. If the Ti film 104 is very thin, the Ti film 104 may be modified into the TiN film 113 during the formation of the TiN film 105 subsequent to the formation of the Ti film 104. The nitrogen concentration of the TiN film 113 is lower than the nitrogen concentration of the TiN film 105 on the TiN film 113. During the modification of the Ti film 104 into the TiN film 113, the Ti film 104 may take nitrogen also from the high dielectric constant gate insulating film 103 (specifically, an HfSiON film) provided under the Ti film 104, and consequently, the nitrogen concentration of the HfSiON film may decrease.

In other words, by the modification of the Ti film 104 into the TiN film 113, a total thickness of the three layered TiN film (i.e., the TiN films 113, 105 and 107) included in the gate electrode 109A in the PFET region is increased, and thus, the nitrogen concentration of the three layered TiN film decreases as a whole. Alternatively, the TiN film 113 whose nitrogen concentration is low is formed in contact with the high dielectric constant gate insulating film 103, and thus, the nitrogen concentration of the HfSiON film serving as the high dielectric constant gate insulating film 103 decreases. In both cases, the work function of the PFET is increased. Specifically, the work function of the PFET can be set to about 4.9 eV or more in the present embodiment.

On the other hand, the TiN film 107 included in the gate electrode 109B in the NFET region is formed to have a relatively high nitrogen concentration, and a small thickness of about 2 nm. Both of these conditions decrease the work function of the NFET. Specifically, the work function of the NFET can be set to about 4.3 eV or less in the present embodiment.

As described above, in the present embodiment, the Ti film 104 and the TiN film 105 having a large thickness and a low nitrogen concentration are formed on both of the PFET region and the NFET region of the semiconductor substrate 101. Then, parts of the TiN film 105 and the Ti film 104 which are located in the NFET region are removed. The TiN film 107 having a small thickness and a high nitrogen concentration is formed thereafter on the NFET region. Consequently, it is possible to form the gate electrode 109A which includes a metal electrode having a large thickness and a low nitrogen concentration (i.e., the gate electrode 109A having a high work function) in the PFET region, and possible to form the gate electrode 109B which includes a metal electrode having a small thickness and a high nitrogen concentration (i.e., the gate electrode 109B having a low work function) in the NFET region.

Accordingly, work function values required for FETs of respective polarities can be obtained in a high-k/metal gate electrode structure.

In the present embodiment, the work functions are adjusted to be suitable for a respective plurality of FETs of opposite polarities, i.e., an N type FET and a P type FET. Instead, the work functions may be adjusted to be suitable for a respective plurality of FETs of the same polarity (e.g., a FET used for a memory, and a FET used for a logic) by making fine adjustments to a thickness or a nitrogen concentration of a metal nitride film, such as a TiN film.

In the present embodiment, the same high dielectric constant gate insulating film 103 is formed on the NFET region and the PFET region. Instead, the type of the gate insulating film formed on each of the NFET region and the PFET region may differ between the NFET region and the PFET region. In this case, the work function can be further adjusted by adjusting, for example, a Hf concentration of the HfSiON layer forming the high dielectric constant gate insulating film 103. Further, as a high dielectric constant layer forming the high dielectric constant gate insulating film 103, the HfSiON layer may be replaced with a HfSiO layer or a HfO₂ layer which are not nitrided. Further, an ultra thin layer (about 1 nm) made of a material capable of changing a work function (e.g., a LaO layer, an AlO layer, a La layer, an Al layer, etc.) may be deposited on the high dielectric constant gate insulating film 103 to further adjust the work function.

In the present embodiment, the TiN films 105 and 107 are formed by PVD. Instead, atomic layer deposition (ALD) or chemical vapor deposition (CVD) may be used to form the TiN films 105 and 107.

In the present embodiment, the TiN films 105 and 107 are used as metal nitride films which are included in the gate electrodes 109A and 109B, respectively, in the FET regions. Instead, other metal nitride films, such as a TaN film, may be used. Further, the Ti film 104 may be replaced with a film made of a metal such as Ta which is different from Ti contained in the TiN film 105.

### Second Embodiment

A semiconductor device and a fabrication method thereof according to the second embodiment of the present disclosure will be described below with reference to the drawings.

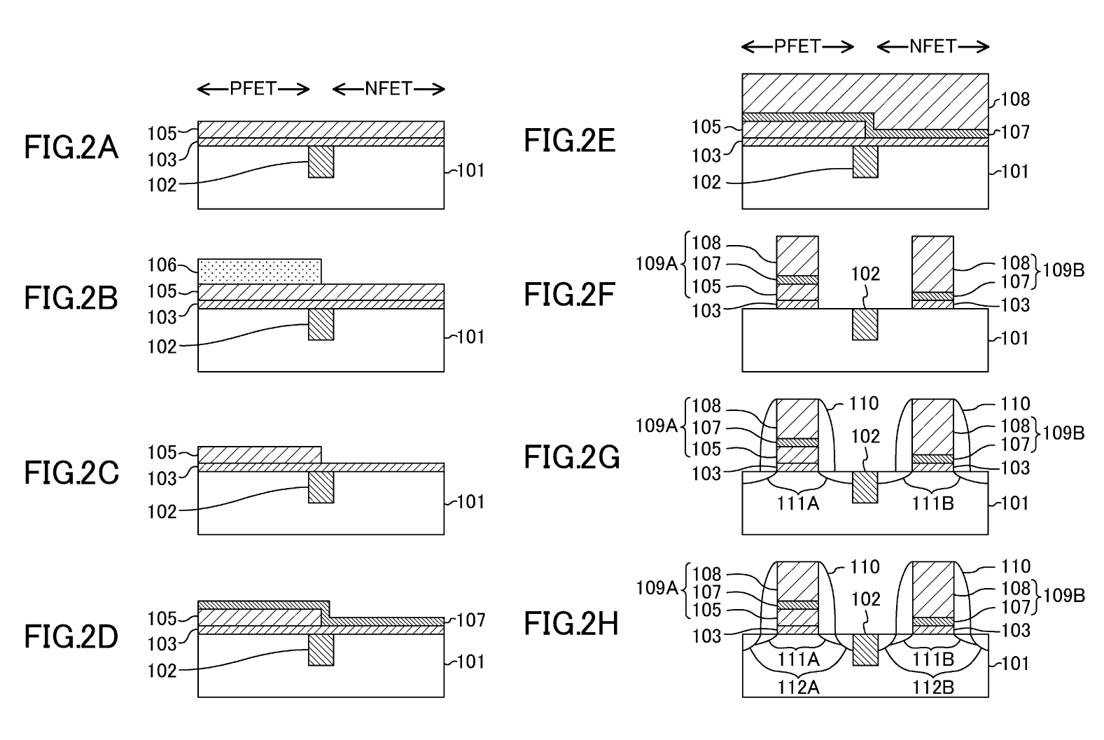

FIGS. 2A-2H are cross-sectional views for illustrating the steps of fabricating the semiconductor device according to the second embodiment.

First, as shown in FIG. 2A, an isolation structure 102 such as an STI structure is formed in a semiconductor substrate 101 to partition the semiconductor substrate 101 into an NFET region and a PFET region. Then, impurity implantation and activation are performed on the semiconductor substrate 101 in each FET region to adjust a threshold voltage (Vt). After that, an oxide film (not shown) on the surface of the semiconductor substrate 101 is removed. Subsequently, a thermal oxidation film having a thickness, for example, of about 1.5 nm, and a HfSiO film having a thickness, for example, of about 2.0 nm are sequentially deposited on the semiconductor substrate 101. The HfSiO film is nitrided to form a high dielectric constant gate insulating film 103 having a HfSiON/SiO₂ structure.

Next, as shown in FIG. 2B, a TiN film 105 having a thickness of about 20 nm is deposited on the high dielectric constant gate insulating film 103 by PVD, for example.

In the present embodiment, it is preferable to select the thickness of the TiN film 105 from a range of relatively large values, e.g., a value range of about 10 nm to 30 nm, to achieve a high work function. Further, it is preferable to set a nitrogen flow ratio (e.g., (N₂ flow rate)/(Ar flow rate+N₂ flow rate)) at the deposition of the TiN film 105 by PVD to a relatively low percentage, e.g., 40% or so, to reduce the nitrogen concentration of the TiN film 105 as much as possible, and achieve a high work function. If the nitrogen flow ratio is set to a low percentage, i.e., 40% or less, attention has to be paid because not a TiN film, but a Ti film may sometimes be deposited.

Next, a mask pattern 106 having an opening at the NFET region is formed on the TiN film 105 as shown in FIG. 2B. Then, part of the TiN film 105 that is located in the NFET region is removed by, for example, wet etching, and the mask pattern 106 is removed thereafter, as shown in FIG. 2C. Consequently, part of the high dielectric constant gate insulating film 103 that is located in the NFET region is exposed. Here, examples of a wet etchant include an etchant by which an etch selectivity of the TiN film 105 to the high dielectric constant gate insulating film 103 becomes relatively high, and by which the TiN film 105 is etched at a relatively low etch rate (i.e., an etchant by which etching can be easily controlled), such as a dilute SPM solution.

Next, as shown in FIG. 2D, a TiN film 107 having a thickness of about 2 nm is deposited on the entire surface of the semiconductor substrate 101, including part of an upper surface of the high dielectric constant gate insulating film 103 that is located in the NFET region (i.e., the portion where the high dielectric constant gate insulating film 103 is exposed) by, for example, setting a nitrogen flow ratio (e.g., (N₂ flow rate)/(Ar flow rate+N₂ flow rate)) to about 80% in PVD.

In the present embodiment, it is preferable to select the thickness of the TiN film 107 from a range of relatively small values, e.g., a value range of about 1 nm to 5 nm, to achieve a low work function. Further, it is preferable to select a nitrogen flow ratio at the deposition of the TiN film 107 by PVD from a range of relatively large values, e.g., a value range of about 80% to 100%, to increase the nitrogen concentration of the TiN film 107 as much as possible, and achieve a low work function.

Next, a polysilicon film 108 having a thickness, for example, of about 100 nm is deposited on the TiN film 107 as shown in FIG. 2E. Then, by gate patterning, a gate electrode 109A made of the TiN film 105, the TiN film 107 and the polysilicon film 108 is formed in the PFET region, and a gate electrode 109B made of the TiN film 107 and the polysilicon film 108 is formed in the NFET region, as shown in FIG. 2F. Here, part of the high dielectric constant gate insulating film 103 that is located outside the gate electrodes 109A and 109B is removed.

Next, impurities are implanted in the semiconductor substrate 101 using the gate electrodes 109A and 109B as masks to form an LDD region 111A in the PFET region, and an LDD region 111B in the NFET region, as shown in FIG. 2G. After that, insulating sidewall spacers 110 are formed on the side surfaces of the gate electrodes 109A and 109B.

Next, impurities are implanted in the semiconductor substrate 101 using the gate electrodes 109A and 109B and the insulating sidewall spacers 110 as masks to form a source/drain region 112A in the PFET region, and a source/drain region 112B in the NFET region, as shown in FIG. 2H. Then, a heat treatment for activating the impurities in the source/drain regions 112A and 112B is performed, and thereafter, a silicide layer (not shown) containing, for example, Ni is formed in upper portions of the gate electrodes 109A and 109B and upper portions of the source/drain regions 112A and 112B to obtain a transistor structure.

In the gate electrode structure eventually obtained in the present embodiment, a total thickness of the two layered TiN film (i.e., the TiN films 105 and 107) included in the gate electrode 109A in the PFET region is thick, i.e., 22 nm or so, and thus, the nitrogen concentration of the two layered TiN film is low as a whole. Both of theses conditions increase the work function of the PFET. Specifically, the work function of the PFET can be set to about 4.9 eV or more in the present embodiment.

On the other hand, the TiN film 107 included in the gate electrode 109B in the NFET region is formed to have a relatively high nitrogen concentration, and a small thickness of about 2 nm. Both of these conditions decrease the work function of the NFET. Specifically, the work function of the NFET can be set to about 4.3 eV or less in the present embodiment.

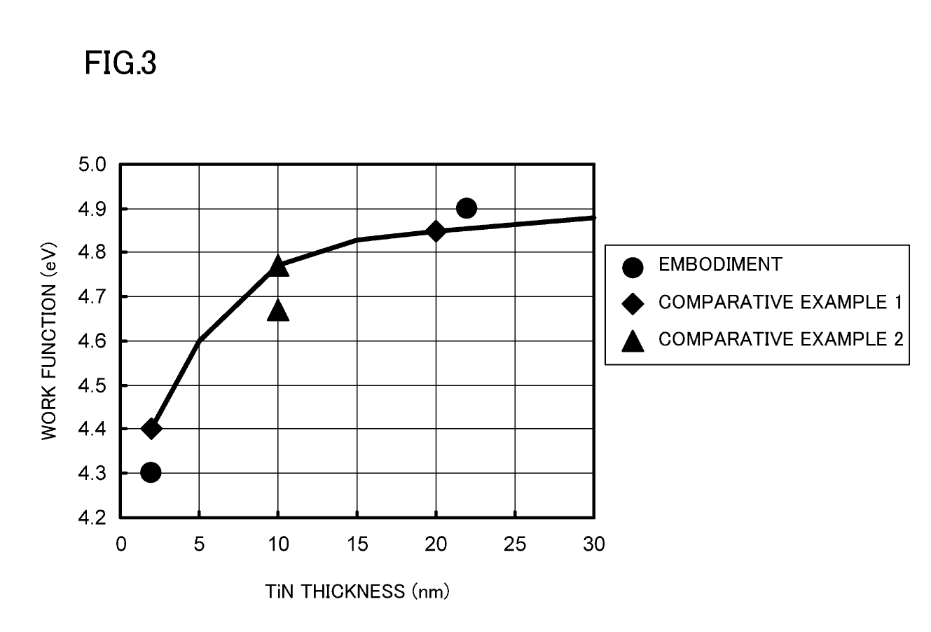

FIG. 3 is a diagram showing the correlation between a thickness of the TiN film in the gate electrode and a work function (the correlation is shown in bold line in the diagram) together with work function values obtained in the present embodiment, the first conventional method (Comparative Example 1) and the second conventional method (Comparative Example 2). As shown in the correlation in FIG. 3, it is possible to expect a work function of about 4.85 eV by setting the thickness of the TiN film to about 22 nm, and it is possible to expect a work function of about 4.4 eV by setting the thickness of the TiN film to about 2 nm. Further, by adjusting the nitrogen concentration of the TiN film as described in the present embodiment, a work function of about 4.9 eV can be obtained in the PFET, and a work function of about 4.3 eV can be obtained in the NFET (see the black circles in the diagram). Since the work function required for the PFET is about 4.9 eV, and the work function required for NFET is about 4.3 eV, the work functions required for both FETs can be obtained in the present embodiment.

On the other hand, as indicated by the black squares (Comparative Example 1) in FIG. 3, even if the thicknesses of the TiN films are set to 2.5 nm and 20 nm, the corresponding work functions can only be about 4.4 eV and about 4.85 eV, respectively, which are not within a required work function. Also, as indicated by the black triangles (Comparative Example 2) in FIG. 3, even if nitrogen is implanted in the TiN film to adjust the work function, the nitrogen implantation results in only reducing the work function of the NFET by about 0.1 eV, and therefore, it is not possible to achieve desired work functions of both of the NFET and the PFET at the same time.

As described above, in the present embodiment, the TiN film 105 having a large thickness and a low nitrogen concentration is formed on both of the PFET region and the NFET region of the semiconductor substrate 101, and part of the TiN film 105 that is located in the NFET region is removed. Then, the TiN film 107 having a small thickness and a high nitrogen concentration is formed on the NFET region. Consequently, it is possible to form the gate electrode 109A which includes a metal electrode having a large thickness and a low nitrogen concentration (i.e., the gate electrode 109A having a high work function) in the PFET region, and possible to form the gate electrode 109B which includes a metal electrode having a small thickness and a high nitrogen concentration (i.e., the gate electrode 109B having a low work function) in the NFET region.

Accordingly, work function values required for FETs of respective polarities can be obtained in a high-k/metal gate electrode structure.

In the present embodiment, the work functions are adjusted to be suitable for a respective plurality of FETs of opposite polarities, i.e., an N type FET and a P type FET. Instead, the work functions may be adjusted to be suitable for a respective plurality of FETs of the same polarity (e.g., a FET used for a memory, and a FET used for a logic) by making fine adjustments to a thickness or a nitrogen concentration of a metal nitride film, such as a TiN film.

In the present embodiment, the same high dielectric constant gate insulating film 103 is formed on the NFET region and the PFET region. Instead, the type of the gate insulating film formed on each of the NFET region and the PFET region may differ between the NFET region and the PFET region. In this case, the work function can be further adjusted by adjusting, for example, a Hf concentration of the HfSiON layer forming the high dielectric constant gate insulating film 103. Further, as a high dielectric constant layer forming the high dielectric constant gate insulating film 103, the HfSiON layer may be replaced with a HfSiO layer or a HfO₂ layer which are not nitrided. Further, an ultra thin layer (about 1 nm) made of a material capable of changing a work function (e.g., a LaO layer, an AlO layer, a La layer, an Al layer, etc.) may be deposited on the high dielectric constant gate insulating film 103 to further adjust the work function.

In the present embodiment, the TiN films 105 and 107 are formed by PVD. Instead, ALD or CVD may be used to form the TiN films 105 and 107.

In the present embodiment, the TiN films 105 and 107 are used as metal nitride films which are included in the gate electrodes 109A and 109B, respectively, in the FET regions. Instead, other metal nitride films, such as a TaN film, may be used.

What is claimed is:

1. A method for fabricating a semiconductor device comprising:
a first step of forming a gate insulating film on a semiconductor substrate having a first region in which a first conductivity type transistor is formed and a second region in which a second conductivity type transistor is formed;
a second step of sequentially forming a metal film and a first metal nitride film on the gate insulating film;
a third step of removing part of each of the metal film and the first metal nitride film that is located in the second region, thereby exposing part of the gate insulating film that is located in the second region, and
at a later time than the third step, a forth step of forming a second metal nitride film made of a same metal nitride as the first metal nitride film on the part of the gate insulating film that is located in the second region.

2. The method of claim 1, wherein the first metal nitride film is made of a nitride of a metal which forms the metal film.

3. The method of claim 1, wherein
in the fourth step, the second metal nitride film is also formed on part of the gate insulating film that is located in the first region, and
the method further comprises:
at a later time than the fourth step, a fifth step of patterning at least the second metal nitride film, the first metal nitride film and the metal film in the first region, thereby forming a first gate electrode; and
at a later time than the fourth step, a sixth step of patterning at least the second metal nitride film in the second region, thereby forming a second gate electrode.

4. The method of claim 3, further comprising:
a seventh step of forming a conductive film on the second metal nitride film at a later time than the fourth step and prior to each of the fifth step and the sixth step, wherein
in the fifth step, the first gate electrode is formed by patterning the conductive film, the second metal nitride film, the first metal nitride film and the metal film, and
in the sixth step, the second gate electrode is formed by patterning the conductive film and the second metal nitride film.

5. The method of claim 4, further comprising:
at a later time than the seventh step, an eighth step of changing the metal film to a third metal nitride film by performing a heat treatment at a temperature of 800° C. or higher.

6. The method of claim 5, wherein a nitrogen concentration of the third metal nitride film is lower than a nitrogen concentration of the first metal nitride film.

7. The method of claim 5, wherein
the gate insulating film includes nitrogen, and
a nitrogen concentration of the gate insulating film is decreased in the eighth step.

8. A method for fabricating a semiconductor device comprising:
a first step of forming a gate insulating film on a semiconductor substrate having a first region in which a first conductivity type transistor is formed and a second region in which a second conductivity type transistor is formed;
a second step of forming a first metal nitride film on the gate insulating film;
a third step of removing part of the first metal nitride film that is located in the second region, thereby exposing part of the gate insulating film that is located in the second region; and
at a later time than the third step, a fourth step of forming a second metal nitride film made of a same metal nitride as the first metal nitride film on the part of the gate insulating film that is located in the second region, wherein
the first metal nitride film has a nitrogen concentration and a thickness which are different from a nitrogen concentration and a thickness of the second metal nitride film.

9. The method of claim 8, wherein
in the fourth step, the second metal nitride film is also formed on part of the gate insulating film that is located in the first region, and
the method further comprises:
at a later time than the fourth step, a fifth step of patterning at least the second metal nitride film and the first metal nitride film in the first region, thereby forming a first gate electrode; and
at a later time than the fourth step, a sixth step of patterning at least the second metal nitride film in the second region, thereby forming a second gate electrode.

10. The method of claim 9, further comprising:
a seventh step of forming a conductive film on the second metal nitride film at a later time than the fourth step and prior to each of the fifth step and the sixth step, wherein
in the fifth step, the first gate electrode is formed by patterning the conductive film, the second metal nitride film and the first metal nitride film, and
in the sixth step, the second gate electrode is formed by patterning the conductive film and the second metal nitride film.

11. The method of claim 1, wherein each of the first metal nitride film and the second metal nitride film is made of TiN.

12. The method of claim 1, wherein a nitrogen concentration of the second metal nitride film is higher than a nitrogen concentration of the first metal nitride film.

13. The method of claim 1, wherein the second metal nitride film has a smaller thickness than the first metal nitride film.

14. The method of claim 1, wherein the gate insulating film includes a high dielectric constant insulating film.

15. The method of claim 1, wherein each of the first metal nitride film and the second metal nitride film is formed by PVD.

16. The method of claim 15, wherein each of the first metal nitride film and the second metal nitride film is formed in a different ratio of a nitrogen gas flow rate to a total gas flow rate.

17. The method of claim 1, wherein
the first conductivity type transistor is a Pch transistor, and
the second conductivity type transistor is an Nch transistor.

18. The method of claim 1, wherein the first conductivity type transistor and the second conductivity type transistor are of a same conductivity type.
